(19) United States
(12) Patent Application Publication
(10) Pub. No.: US 2010/0013053 A1
(43) Pub. Date: Jan. 21, 2010

(54) METHOD FOR MANUFACTURING III-V COMPOUND SEMICONDUCTOR SUBSTRATE, METHOD FOR MANUFACTURING EPITAXIAL WAFER, III-V COMPOUND SEMICONDUCTOR SUBSTRATE, AND EPITAXIAL WAFER

(75) Inventors: Masahiro NAKAYAMA, Itami-shi (JP); Yasuaki Higuchi, Itami-shi (JP)

Correspondence Address: DRINKER BIDDLE & REATH (DC), 1500 K STREET, N.W., SUITE 1100, WASHINGTON, DC, 20005-1209, US

(73) Assignee: SUMITOMO ELECTRIC INDUSTRIES, LTD., Osaka-shi (JP)

(21) Appl. No.: 12/499,158

(22) Filed: Jul. 8, 2009

(30) Foreign Application Priority Data
Jul. 18, 2008 (JP) 2008-187303

(51) Int. Cl. H01L 29/20; H01L 21/302; H01L 21/20

(52) U.S. Cl. 257/615; 438/758; 438/478; 257/E21.214; 257/E21.09; 257/E29.089

(57) ABSTRACT

The present invention provides a method for manufacturing a III-V compound semiconductor substrate, a method for manufacturing an epitaxial wafer, a III-V compound semiconductor substrate, and an epitaxial wafer, wherein the thickness of an oxide film formed on the substrate or in the wafer is controlled with high precision, and surface of the epitaxial wafer is prevented from getting rough,. The method for manufacturing a III-V compound semiconductor substrate according to the present invention includes the following steps. Initially, a substrate composed of a III-V compound semiconductor is provided. Thereafter, the resulting substrate is cleaned with an acidic solution. Subsequently, an oxide film is formed on the substrate by a wet method after the cleaning.

### BACKGROUND OF THE INVENTION

1. Field of the Invention

The present invention relates to a method for manufacturing a III-V compound semiconductor substrate, a method for manufacturing an epitaxial wafer, a III-V compound semiconductor substrate, and an epitaxial wafer. In particular, it relates to a method for manufacturing a III-V compound semiconductor substrate, a method for manufacturing an epitaxial wafer, a III-V compound semiconductor substrate, and an epitaxial wafer, which are suitably used for devices, e.g., field effect transistors (FET) and high electron mobility transistors (HEMT)

2. Description of the Related Art

III-V compound semiconductor substrates have high-performance amplifying function and switch function in the field of cellular phones and, therefore, are used as base materials for wireless communication devices, e.g., FET, HEMT, and heterojunction bipolar transistors (HBT). At present, in production of HEMT devices used for cellular phones and the like, a thin film epitaxial layer, e.g., a gallium arsenide (GaAs) layer, an aluminum gallium arsenide (AlGaAs) layer, or an indium gallium arsenide (InGaAs) layer, is formed on, for example, a GaAs substrate by a metal-organic vapor phase epitaxy (MOVPE) method, a molecular beam epitaxy (MBE) method, or the like. In this case, if impurities and the like are adhered to a surface of the GaAs substrate or the like, a good-quality epitaxial layer is not obtained. In addition, the device characteristics deteriorate thereafter. For example, it has been known that if impurities which emit free electrons are present at an interface between the epitaxial layer and the GaAs substrate, such impurities are exerted on the pinch-off characteristics and the drain breakdown voltage of a device. In order to avoid such a defective, heretofore, impurities on the surface have been removed by conducting wet etching of the GaAs substrate surface before epitaxial growth. Alternatively, impurities have been removed by conducting cleaning of the GaAs substrate surface with an introduced gas, heat, or the like after the GaAs substrate has been disposed in an epitaxial growth apparatus.

However, even if the above-described pretreatment and cleaning are conducted, it is difficult to avoid contamination with a very small amount of components in a clean room atmosphere or an apparatus. For example, silicon (Si) having a high Clarke number or the like adheres to a semiconductor substrate relatively easily even in a controlled environment, and is accumulated at an interface between the GaAs substrate and the epitaxial layer so as to come into the state of emitting free electrons. As a result, the above-described device has deteriorated characteristics.

Japanese Unexamined Patent Application Publication No. 9-320967 discloses a method for manufacturing a compound semiconductor wafer, wherein an oxide film having a thickness of 2 to 30 nm is formed on a III-V compound semiconductor substrate through application of ultraviolet ozone, as a means for solving the above-disadvantage. This document discloses that Si remaining in the vicinity of the interface between the III-V compound semiconductor substrate and the epitaxial layer is made electrically inactive by forming the oxide film.

Furthermore, Japanese Unexamined Patent Application Publication No. 11-126766 discloses a method for cleaning a semiconductor crystal wafer, wherein an oxide film is formed through immersion into ozone-containing ultrapure water and, thereafter, the oxide film is removed by conducting cleaning with an alkaline solution or a mixed solution of alkali and acid. This document discloses that impurities remaining on a surface of the III-V compound semiconductor substrate are removed.

Moreover, Japanese Unexamined Patent Application Publication No. 2003-206199 discloses a compound semiconductor crystal in which the ratio of oxygen (O) and Si present at an interface between a III-V compound semiconductor substrate and an epitaxial layer is 2 or more. This document discloses that Si simple substance is prevented from existing at the interface by chemically combining Si and O so as to generate silicon dioxide (SiO₂).

In addition, Japanese Unexamined Patent Application Publication No.2006-128651 discloses a semiconductor device including a Si oxide film, wherein the haze of the Si oxide film surface is 10 ppm or less. This document discloses that Si and Si compounds present on a surface of the III-V compound semiconductor substrate are inactivated by the Si oxide film and, thereby, there is no accumulation of carrier due to the action of Si as a donor and the surface morphology does not deteriorate.

### SUMMARY OF THE INVENTION

However, in Japanese Unexamined Patent Application Publication No. 9-320967, ultraviolet ozone is applied by using an ultraviolet (UV) ozone generator. That is, since oxygen present on the III-V compound semiconductor substrate is ozonized with ultraviolet rays to generate ozone, it is difficult to control the amount of oxygen required for obtaining an oxide film optimum for inactivating Si which is an impurity remaining on the III-V compound semiconductor substrate. Therefore, in the invention disclosed in this document, controllability, which is required for forming a desired oxide film, is poor. Furthermore, since the ozone density in the gas becomes small, variations occur in concentration of ozone which contacts the surface of the III-V compound semiconductor substrate. Consequently, variations occur in thickness of the oxide film.

Regarding the above-described four inventions, relatively large amounts of oxygen is present on the surfaces of the III-V compound semiconductor substrates. As the degree of oxidation of the surface increases, the surface of the III-V compound semiconductor substrate is covered with the oxide film. Consequently, there is a problem in that surface of the epitaxial layer gets roughening at an atomic level because lattice matching between the III-V compound semiconductor substrate surface and the epitaxial layer becomes poor or step growth becomes difficult.

Moreover, in Japanese Unexamined Patent Application Publication No. 11-126766, the oxide film is formed on the surface by using ozone water. The ozone water is a neutral liquid. In general, in the case where the III-V compound semiconductor substrate is treated with pure water (neutral) or an alkaline solution, group V oxides are removed easily, and in the case where the treatment is conducted with an acidic solution, group III oxides are removed easily. Therefore, in the case where the treatment is conducted with the neutral ozone water, as in this document, the substrate surface of the III-V compound semiconductor becomes a group III-rich surface easily on a stoichiometry basis. In a temperature increase step of epitaxial growth, dissociation of group V element occurs more easily than dissociation of group III element does. Consequently, as the epitaxial layer grows, group III oxides remain easily and the surface tends to become rich in group III following the stoichiometry in the substrate state. This unbalance in stoichiometry becomes one of causes of surface roughening of the epitaxial layer.

The present invention has been made in order to solve the above-described problems. Accordingly, it is an object of the present invention to provide a method for manufacturing a III-V compound semiconductor substrate, a method for manufacturing an epitaxial wafer, a III-V compound semiconductor substrate, and an epitaxial wafer, wherein, in the a III-V compound semiconductor substrate and an epitaxial wafer, the thickness of an oxide film therein or thereon can be controlled with high precision, and surface roughening is suppressed in formation of an epitaxial layer.

A method for manufacturing a III-V compound semiconductor substrate according to the present invention includes the steps of preparing a substrate composed of a III-V compound semiconductor (hereafter may be simply referred to as preparation step), cleaning the above-described substrate with an acidic solution (hereafter may be simply referred to as cleaning step), and forming an oxide film on the above-described substrate by a wet method after the above-described cleaning (hereafter may be simply referred to as oxide film formation step or formation step).

According to the method for manufacturing a III-V compound semiconductor substrate of an aspect of the present invention, the substrate is cleaned with the acidic solution before the oxide film is formed. The inventor of the present invention conducted intensive research and, as a result, found that in the case where a substrate was cleaned with an acidic solution, group V atoms were present on the surface of the substrate to a relatively large extent, and group III atoms were present to a relatively small extent. In the formation of the epitaxial layer by using the III-V compound semiconductor substrate, since the dissociation pressure of the group V elements is high in a temperature increase step of the growth, group V atoms dissociate easily. However, a large amount of group V atoms exist on the surface of the III-V compound semiconductor substrate according to an aspect of the present invention, and loss of group V atoms on the surface due to formation of the epitaxial layer can be suppressed. Consequently, group V atoms and group III atoms on the surface of the epitaxial layer can be made comparable to each other in the stoichiometric balance. Because this invention is provided with this balance between the group III atoms and the group V atoms, the surface of the epitaxial layer can be made smooth, and surface roughening of the epitaxial layer can be suppressed.

Furthermore, the oxide film is formed by the wet method. In the wet method, the thickness of the oxide film can be controlled easily by controlling the oxidizing agent concentration in the solution and the substrate treatment time. Consequently, the thickness of the oxide film can be controlled with high precision.

Incidentally, in the case where the oxide film is formed on the substrate surface, oxygen thereof forms a deep impurity level in the III-V compound semiconductor in the epitaxial growth step and functions to capture free electrons of Si. Free electrons can be inactivated by providing an optimum amount of oxide film for compensation of Si carriers present on the substrate surface. Consequently, formation of the oxide film advantageously contributes to the device characteristics, e.g., the pinch-off characteristics and the drain breakdown voltage.

As described above, the III-V compound semiconductor substrate can be produced, in which carriers at the interface between the substrate and the epitaxial layer are rendered harmless by controlling the thickness of the oxide film and, in addition, surface roughening of the epitaxial layer is suppressed by cleaning with the acidic solution.

In the above-described method for manufacturing a III-V compound semiconductor substrate, it is preferable that in the above-described oxide film formation step, the oxide film having a thickness of 15 Å or more, and 30 Å or less is formed.

In the case where the thickness of the oxide film is 15 Å or more, Si can be effectively inactivated by O in the oxide film. Consequently, an influence of Si functioning as a carrier can be reduced. On the other hand, in the case where the thickness of the oxide film is 30 Å or less, when an epitaxial layer is formed on the III-V compound semiconductor substrate, an influence of the oxide film exerted on surface roughness of the epitaxial layer can be reduced and, thereby suppressing the surface roughening effectively.

In the above-described method for manufacturing a III-V compound semiconductor substrate, it is preferable that in the cleaning step, the acidic solution having a pH of 6 or less is used.

According to the above, a large amount of group V atoms exist (group V atom rich) on the surface of the substrate, and the balance in the stoichiometry on the surface after growth of the epitaxial layer can be maintained. Consequently, the surface of the epitaxial layer can be further prevented from getting rough.

In the above-described method for manufacturing a III-V compound semiconductor substrate, it is preferable that in the oxide film formation step, the oxide film is formed by using hydrogen peroxide water.

The decomposition rate of hydrogen peroxide water is very small, and the oxygen concentration in the solution exhibits high stability with time. Therefore, the thickness of the oxide film is successfully controlled. Consequently the oxide film can be formed with good reproducibility.

In the above-described method for manufacturing a III-V compound semiconductor substrate, it is preferable that in the preparation step, the substrate composed of gallium arsenide (GaAs), indium phosphide (InP), or gallium nitride (GaN) is prepared.

Consequently, the III-V compound semiconductor substrate useful as a semiconductor element can be produced.

A method for manufacturing an epitaxial wafer, according to an aspect of the present invention, includes the steps of producing a III-V compound semiconductor substrate by any one of the above-described methods for manufacturing a III-V compound semiconductor substrate and forming an epitaxial layer on the III-V compound semiconductor substrate.

According to the method for manufacturing an epitaxial wafer of an aspect of the present invention, initially, a III-V compound semiconductor substrate surface is controlled by using an acidic solution to become rich in group V element and, thereafter, an epitaxial layer is formed on the III-V compound semiconductor substrate in which the thickness of the oxide film is controlled with good reproducibility. Since group V elements existing on the surface of the III-V compound semiconductor substrate is relatively increased in amount by the treatment with an acidic solution, loss of group V elements on the surface of the epitaxial layer formed thereon is suppressed. Therefore, surface roughening of the epitaxial layer can be suppressed because of well-balanced relation in amount between the group III elements and the group V elements. Furthermore, since the thickness of the oxide film is successfully controlled, Si carriers can be compensated with high precision (with good reproducibility) and be rendered harmless. Consequently, the produced epitaxial wafer advantageously contributes to the device characteristics, e.g., the pinch-off characteristics and the drain breakdown voltage.

A III-V compound semiconductor substrate according to an aspect of the present invention is produced by any one of the above-described methods for manufacturing a III-V compound semiconductor substrate.

According to the III-V compound semiconductor substrate of an aspect of the present invention, it includes a substrate having a surface on which group V atoms exist in relatively large numbers and group III atoms exist in relatively small number. On the other hand, in the formation of the epitaxial layer, since the dissociation pressure of the group V elements is high in a temperature increase step of the growth, group V elements dissociate easily. That is, the group V atoms and the group III atoms on the surface of the epitaxial layer become comparable with well-balanced stoichiometric after the epitaxial growth. Consequently, the epitaxial layer can be prevented from getting rough on the surface thereof in the formation of the epitaxial layer on the III-V compound semiconductor substrate.

The III-V compound semiconductor substrate according to an aspect of the present invention includes the oxide film having a thickness controlled with high precision. Consequently, Si carriers can be inactivated, so that the characteristics of a semiconductor element can be improved when the semiconductor element is formed by using this III-V compound semiconductor substrate.

In the above-described III-V compound semiconductor substrate, it is preferable that the oxide film has a thickness of 15 Å or more, and 30 Å or less.

In the case where the thickness of the oxide film is 15 Å or more, Si carriers are inactivated sufficiently. Consequently, the characteristics of a semiconductor element can be improved when the semiconductor element is formed by using this III-V compound semiconductor substrate. In the case where the thickness of the oxide film is 30 Å or less, when an epitaxial layer is formed on the III-V compound semiconductor substrate, an influence of the oxide film exerted on surface roughness of the epitaxial layer is reduced and, thereby suppressing the surface roughening effectively.

An epitaxial wafer according to an aspect of the present invention includes any one of the above-described III-V compound semiconductor substrates and an epitaxial layer disposed on the III-V compound semiconductor substrate.

According to the epitaxial wafer of an aspect of the present invention, an epitaxial layer is formed on the III-V compound semiconductor substrate in which the surface is controlled to become rich in group V element and, in addition, the thickness of the oxide film is controlled with good reproducibility. Since loss of group V elements is suppressed, the epitaxial layer's surface roughening is suppressed. Furthermore, since variations in thickness of the oxide film are suppressed, the amount of inactivated Si is able to be controlled. Consequently, the characteristics of a semiconductor element can be improved when the semiconductor element is formed by using this epitaxial wafer.

Incidentally, in the specification, the term “III-V compound semiconductor substrate” refers to a compound semiconductor substrate containing group III atoms and group V atoms. The term “group III” refers to group IIIB of the old international union of pure and applied chemistry (IUPAC) system, and the term “group V” refers to group VB of the old IUPAC system.

According to the method for manufacturing a III-V compound semiconductor substrate, the method for manufacturing an epitaxial wafer, the III-V compound semiconductor substrate, and the epitaxial wafer of aspects of the present invention, since cleaning is conducted with the acidic solution and the oxide film is formed by the wet method, the thickness of the oxide film can be controlled with high precision and, in addition, the epitaxial layer, which is produced by forming epitaxial layer on the substrate, is provided with the surface prevented from getting rough.

### BRIEF DESCRIPTION OF THE DRAWINGS

FIG. 1 is a sectional view schematically showing a III-V compound semiconductor substrate according to a first embodiment of the present invention;

FIG. 2 is a diagram showing a flow chart of a method for manufacturing a III-V compound semiconductor substrate according to the first embodiment of the present invention;

FIG. 3 is a sectional view schematically showing a treatment apparatus used in a cleaning step according to the first embodiment of the present invention;

FIG. 4 is a sectional view schematically showing an epitaxial wafer according to a second embodiment of the present invention;

FIG. 5 is a sectional view schematically showing the state in which the epitaxial layer includes a plurality of layers, according to the second embodiment of the present invention;

FIG. 6 is a flow chart showing a method for manufacturing an epitaxial wafer according to the second embodiment of the present invention; and

FIG. 7 is a diagram showing the relationship between the thermal cleaning temperature and the sheet resistance at an interface between a III-V compound semiconductor substrate and an epitaxial wafer in the example 2.

### DESCRIPTION OF THE PREFERRED EMBODIMENTS

The embodiments and the examples according to the present invention will be described below with reference to the drawings. In the drawings below, the same or corresponding elements are indicated by the same reference numeral and the explanation thereof will not be repeated.

### First Embodiment

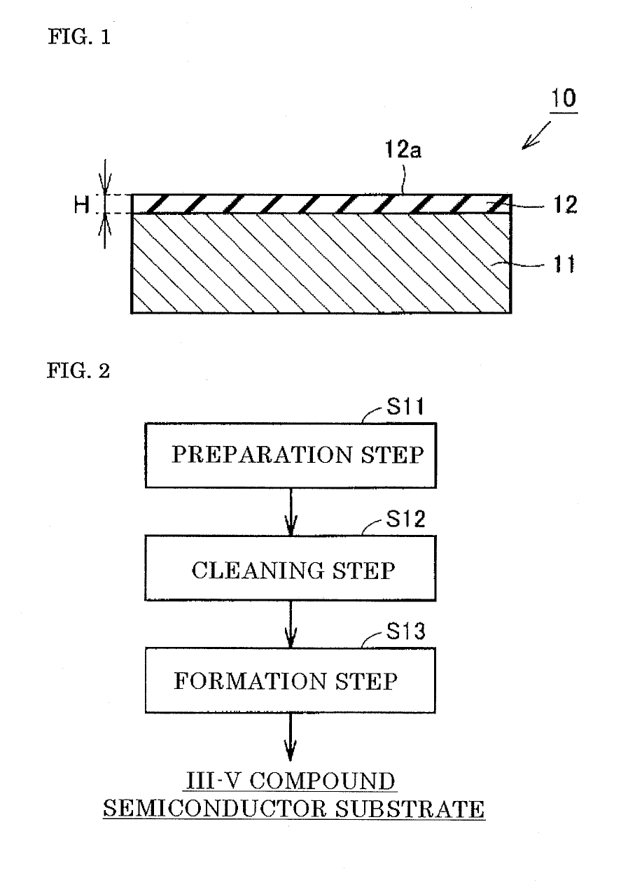

FIG. 1 is a sectional view schematically showing a III-V compound semiconductor substrate according to the present embodiment. The III-V compound semiconductor substrate according to the present embodiment will be described with reference to FIG. 1.

As shown in FIG. 1, a III-V compound semiconductor substrate 10 according to the present embodiment includes a substrate 11 and an oxide film 12. The oxide film 12 is disposed on the substrate 11.

The substrate 11 is composed of a III-V compound semiconductor containing GaAs, InP, GaN, aluminum nitride (AIN), indium nitride (InN), or the like, and preferably containing GaAs, InP, or GaN.

The oxide film 12 has a surface 12a opposite to a surface located on the substrate 11 side. It is preferable that the oxide film 12 has a thickness H of 15 Å or more, and 30 Å or less, and the thickness H of 17 Å or more, and 19 Å or less is more preferable. In the case where the thickness H of the oxide film 12 is 15 Å or more, Si is inactivated sufficiently. Therefore a semiconductor element, which is formed by using this III-V compound semiconductor substrate 10, is provided with the improved characteristics of a semiconductor element. In the case where the thickness H of the oxide film 12 is 17 Å or more, the characteristics of the semiconductor element can be further improved. On the other hand, in the case where the thickness H of the oxide film 12 is 30 Å or less, when an epitaxial layer is formed on the III-V compound semiconductor substrate 10, an influence of the oxide film 12 exerted on surface roughness of the epitaxial layer can be reduced and, thereby, the surface can be prevented from getting rough effectively. The thickness H of the oxide film 12 having 19 Å or less can more effectively suppress the surface roughening.

In this regard, the above-described term “thickness of the oxide film 12” refers to a value of the thickness of the oxide film 12, which is located at nearly center portion of the III-V compound semiconductor substrate 10, measured by using, for example, an ellipsometer.

Furthermore, it is preferable that the oxide film 12 contains group III atoms, group V atoms, O atoms, and Si atoms.

Moreover, it is preferable that the oxidation index of the oxide film 12 is 0.5 or more, and more preferably 0.7 or more. In the case where the oxidation index is 0.5 or more, the substantial thickness H of the oxide film 12 can be determined. In the case where the oxidation index is 0.7 or more, the substantial thickness H of the oxide film 12 can be determined sufficiently.

In this regard, the above-described term “oxidation index of the oxide film 12” refers to a value calculated on the basis of a formula {(group III-O)+(group V-O)}/{(group III-group V)+(group III-O)+(group V-O)} from the bonding number of group III atoms and O atoms (group III-O), the bonding number of group V atoms and O atoms (group V-O), and the bonding number of Ga atoms and As atoms (group III-group V), each measured by, for example an XPS method.

FIG. 2 is a diagram showing a flow chart of a method for manufacturing a III-V compound semiconductor substrate according to the present embodiment. The method for manufacturing a III-V compound semiconductor substrate according to the present embodiment will be described with reference to FIG. 2.

Initially, as shown in FIG. 2, a preparation step (S11) to prepare the substrate 11 composed of a III-V compound semiconductor substrate is carried out. In the preparation step (S11), it is preferable that the substrate 11 composed of GaAs, InP, or GaN is prepared.

Next, a cleaning step (S12) to clean the substrate 11 with an acidic solution is carried out. Group V atoms are prevented from falling off the surface of the substrate 11 by performing the cleaning step (S12). Consequently, the substrate 11 after the cleaning step (S12) has a Group V-rich surface.

In the cleaning step (S12), it is preferable that the pH of the acidic solution used is 6 or less, and the pH of 2.0 or more and 5.5 or less is more preferable. In the case where the pH is 6 or less, group V atoms can be further prevented from falling from the surface of the substrate 11 and, thereby, the surface of the substrate 11 can be made richer in group V atom. In the case where the pH is 5.5 or less, the surface of the substrate 11 can be made still richer in group V atom. On the other hand, in the case where the pH is 2.0 or more, the surface of the substrate 11 can be made rich in group V atom and, in addition, the surface can be prevented from getting rough due to the acidic solution used.

The acidic solution used in the cleaning step (S12) is not specifically limited. For example, dilute hydrochloric acid, dilute sulfuric acid, dilute nitric acid, and organic acids can be used. As for the organic acid, for example, formic acid, acetic acid, oxalic acid, lactic acid, malic acid, and citric acid can be used.

The temperature of the acidic solution used in the cleaning step (S12) is not specifically limited. However, room temperature is preferable. In the case where the temperature is specified to be room temperature, an apparatus for manufacturing the III-V compound semiconductor substrate 10 can be simplified.

Furthermore, the cleaning time is not specifically limited. However, for example, 10 sec or more, and 300 sec or less is preferable. By carrying out the cleaning step (S12) within this range, the cost of the acidic solution can be reduced and the productivity can be improved.

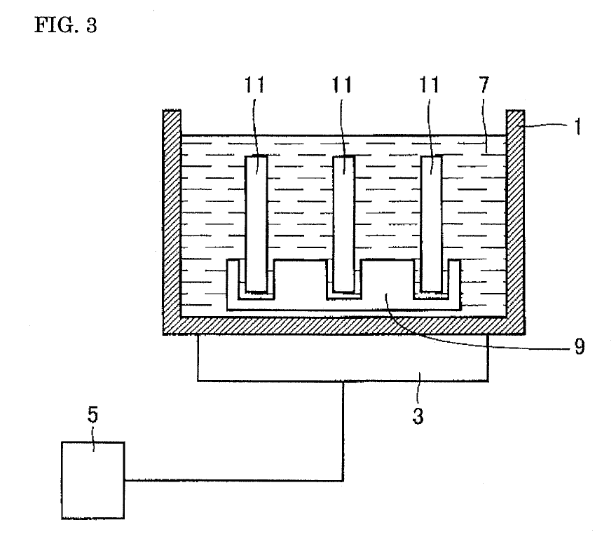

The cleaning step (S12) includes a manner in which a dilute acidic solution having a concentration of a few percent or less is used, and vibration or shaking is applied to the acidic solution by using an ultrasonic apparatus, as shown in FIG. 3. In this regard, FIG. 3 is an example of sectional views schematically showing a treatment apparatus used in the cleaning step of the present embodiment. The manner is not limited to this and may be, for example, a manner of a sheet spin cleaning apparatus or the like. In the case where ultrasonic waves are applied, it is desirable that ultrasonic waves with frequencies in a megahertz band of 900 to 2,000 kHz are used.

As shown in FIG. 3, the treatment apparatus is provided with a cleaning bath 1 to hold an acidic solution 7, an ultrasonic generator 3 disposed on the bottom surface of the cleaning bath 1, and a control portion 5 which is connected to the ultrasonic generator 3 and which controls the ultrasonic generator 3. The acidic solution 7 is held in the inside of the cleaning bath 1. In addition, a holder 9 to hold a plurality of substrates 11 is in the state of being immersed in the acidic solution 7. The plurality of substrates 11 to be cleaned are held by the holder 9. The ultrasonic generator 3 is disposed on the bottom of the cleaning bath 1.

In the case where the substrates 11 are cleaned in the cleaning step (S12), as shown in FIG. 3, a predetermined acidic solution 7 is disposed in the inside of the cleaning bath 1, and the substrates 11 held by the holder 9 are immersed in the acidic solution 7 on a holder 9 basis. In this manner, the surface of the substrate 11 can be cleaned with the cleaning solution 7.

In addition, at this time, ultrasonic waves may be generated by controlling the ultrasonic generator 3 with the control portion 5. As a result, ultrasonic waves are applied to the acidic solution 7. Consequently, since the acidic solution 7 is vibrated, an effect of removing impurities, fine particles, and the like from the substrate 11 can be enhanced. Alternatively, the cleaning bath 1 may be placed on a shakable member, e.g., an XY stage, the member may be shaken and, thereby, the cleaning bath 1 may be shaken so as to agitate (shake) the acidic solution 7 in the inside. Alternatively, the substrate 11 may be shaken on a holder basis 9 by a manual operation or the like so as to agitate (shake) the acidic solution 7. In this case as well, as in the application of ultrasonic waves, an effect of removing impurities, fine particles, and the like from the substrate 11 can be enhanced.

After the cleaning step (S12), a pure water rinse step is performed in order to remove the acidic solution. Furthermore, after the pure water rinse step, moisture of the substrate 11 is removed through centrifugal drying or the like. In the pure water rinse step, adhesion of fine particles to the substrate can be prevented by applying ultrasonic waves of 900 to 2,000 kHz, for example. Moreover, in the pure water rinse step, in order to prevent the surface of the substrate 11 from being oxidized, pure water deaerated to have an oxygen concentration of, for example, 100 ppb or less is used.

Next, the formation step (S13) to form the oxide film 12 on the substrate 11 is performed by a wet method. The wet method refers to a method in which the oxide film 12 is formed by using an oxygen-containing solution. The oxide film 12 can be formed by using, for example, ozone water or hydrogen peroxide water, and it is preferable to use the hydrogen peroxide water. The decomposition rate of the hydrogen peroxide water is very small at room temperature and, therefore, the change in O concentration with time is small and the hydrogen peroxide water is stable. Consequently, the oxide film 12 can increase in thickness with improved precision and good reproducibility.

In the formation step (S13), the oxide film 12 is formed on the surface of the substrate 11 by allowing oxygen to contact the surface of the substrate 11. At this time, it is preferable that the oxide film is formed while incorporating Si atoms. In this manner, the oxide film 12 preferably contains group III atoms, group V atoms, O atoms, and Si atoms.

In the formation step (S13), it is preferable that the oxide film 12 is formed to have a thickness H of 15 Å or more, and 30 Å or less, and more preferably 17 Å or more, and 19 Å or less for the same reason as that described above.

The III-V compound semiconductor substrate 10 shown in FIG. 1 can be produced by carrying out the above-described steps (S11 to S13).

Incidentally, in the present embodiment, the III-V compound semiconductor substrate 10 includes the substrate 11 composed of the III-V compound semiconductor. The III-V compound semiconductor substrate may further include another substrate disposed on a surface of the substrate 11, the surface being opposite to the surface on which the oxide film 12 is disposed. The other substrate may be a III-V compound semiconductor substrate or be composed of other materials. In the case where the III-V compound semiconductor substrate includes another substrate, for example, in the preparation step (S11), a substrate in which the other substrate and the substrate 11 are laminated is prepared.

As described above, the method for manufacturing the III-V compound semiconductor substrate 10 according to the present embodiment includes the cleaning step (S12) to clean the substrate 11 with the acidic solution, and the forming step (S13) to form the oxide film 12 on the substrate 11 by the wet method after the cleaning step (S12).

According to the method for manufacturing the III-V compound semiconductor substrate 10 in the present embodiment, on the surface of the substrate 11 obtained from the cleaning step (S12), group V atoms exist in relatively large number and group III atoms exist in relatively small number. On the other hand, during the formation of the epitaxial layer by using the III-V compound semiconductor substrate 10, group V atoms falls off easily. However, since group V atoms are present on the surface of the III-V compound semiconductor substrate 10 to a large extent, group V atoms unlikely to be small number on the surface of the epitaxial layer when the epitaxial layer is formed. Consequently, degradation in the stoichiometric balance between the group V atoms and group III atoms on the surface of the epitaxial layer can be suppressed. This can prevent the surface of the epitaxial layer from being getting rough.

Moreover, in the formation step (S13), the oxide film is formed by a wet method. According to the wet method, the dissolved oxygen concentration is able to be controlled easily and, in addition, it is able to provide with relatively high oxygen concentration. Consequently, the amount of generation of oxygen is controlled easily and variations in concentration of oxygen in contact with the surface of the substrate 11 can be suppressed. Therefore, variations in thickness of the oxide film 12 can be suppressed.

In the production of the III-V compound semiconductor substrate 10, it has been known that Si is introduced from jigs used in the production process and an atmosphere in a clean room. When the temperature is raised to form an epitaxial layer on the III-V compound semiconductor substrate 10, O atoms in the oxide film 12 are electrically activated together with Si atoms taken in so as to form a deep level. Consequently, Si atoms, which have formed a shallow level, release carriers, and O atoms, which have formed a deep level, capture the carriers so as to electrically neutralize. As a result, the function of Si as an n-type carrier can be suppressed. In the case where a semiconductor element is produced by using the III-V compound semiconductor substrate 10 as described above, the leakage current of the semiconductor element resulting from Si carriers remaining between the III-V compound semiconductor substrate 10 and the epitaxial layer can be suppressed. Therefore, deterioration in characteristics of the semiconductor element can be suppressed.

In addition, changes in the III-V compound semiconductor substrate 10 with time can be suppressed by forming the oxide film 12. Consequently, the convenience of storage of the III-V compound semiconductor substrate 10 can be improved.

### Second Embodiment

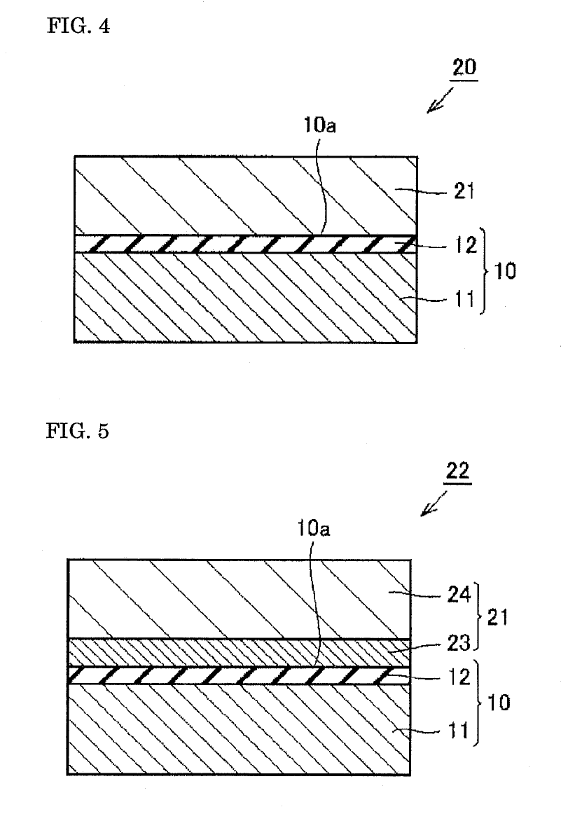

FIG. 4 is a sectional view schematically showing an epitaxial wafer according to the present embodiment. An epitaxial wafer 20 according to the present embodiment will be described with reference to FIG. 4.

As shown in FIG. 4, the epitaxial wafer 20 according to the present embodiment includes the III-V compound semiconductor substrate 10 according to the first embodiment and an epitaxial layer 21 disposed on the III-V compound semiconductor substrate 10. That is, the epitaxial wafer 20 includes the substrate 11, the oxide film 21 disposed on the substrate 11, and the epitaxial layer 21 disposed on the oxide film 12.

The carrier concentration at an interface 10a between the III-V compound semiconductor substrate 10 and the epitaxial layer 21 is preferably less than 5×10¹⁴ cm⁻³, and more preferably 5×10¹³ cm⁻³ or less. Since the epitaxial wafer 20 includes the oxide film 12, carriers resulting from the activation of Si can be reduced. Consequently, the above-described low carrier concentration can be realized. In the case where the carrier concentration is less than 5×10¹⁴ cm⁻³, carriers resulting from activation of Si can be reduced. Therefore, the characteristics of a semiconductor element can be improved when the semiconductor element is formed by using this epitaxial wafer 20. In the case where the carrier concentration is 5×10¹³ cm⁻³ or less, the characteristics of the semiconductor element can be further improved.

The epitaxial layer 21 may be, for example, a III-V compound semiconductor, although not specifically limited. It is preferable that at least one of the elements constituting the substrate 11 is contained.

The epitaxial layer 21 may include a plurality of layers. FIG. 5 is a sectional view schematically showing the state in which the epitaxial layer 21 includes a plurality of layers in the present embodiment. As shown in FIG. 5, the epitaxial layer 21 may include a first layer 23 and a second layer 24 disposed on the first layer 23. In the case where the epitaxial wafer 22 is used for a high electron mobility transistor (HEMT), the first layer 23 is, for example, a high-purity electron transport layer and the second layer 24 is an electron supply layer.

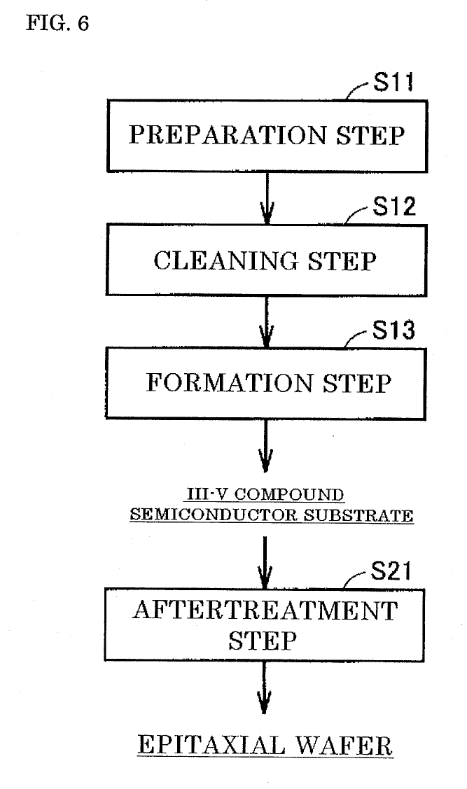

FIG. 6 is a flow chart showing a method for manufacturing an epitaxial wafer according to the present embodiment. The method for manufacturing an epitaxial wafer according to the present embodiment will be described with reference to FIG. 6.

As shown in FIG. 6, the III-V compound semiconductor substrate 10 according to the first embodiment is produced (S11 to S13).

Subsequently, an aftertreatment step (S21) is carried out, in which the epitaxial layer 21 is formed on the III-V compound semiconductor substrate 10. In the aftertreatment step (S21), a film formation treatment is performed, in which the epitaxial layer 21 is formed on the surface of the III-V compound semiconductor substrate 10 through, for example, epitaxial growth, or the like. At this time, it is preferable that a III-V compound semiconductor crystal containing at least one of the elements constituting the substrate 11 is grown. Furthermore, it is preferable that a plurality of elements are formed. At that time, after predetermined structures are formed on the III-V compound semiconductor substrate 10, a division step, which may be dicing, for example, is carried out in order to divide the III-V compound semiconductor substrate 10 into individual semiconductor elements. In this manner, the semiconductor element including the III-V compound semiconductor substrate 10 can be obtained. Such a semiconductor element is mounted on, for example, a lead frame. Then, a wire bonding process or the like is performed and, thereby, a semiconductor device including the above-described element can be obtained.

In this regard, the method for conducting epitaxial growth is not specifically limited. For example, vapor phase epitaxy methods, e.g., a hydride vapor phase epitaxy (HVPE) method, a molecular beam epitaxy (MBE) method, a metal organic chemical vapor deposition (MOCVD) method, and a sublimation method; liquid phase methods, e.g., a flux method, and a high nitrogen pressure solution method; and the like can be adopted.

The epitaxial wafer 20 or 22 shown in FIG. 4 or FIG. 5 can be produced by undergoing the above-described steps (S11 to S13 and S21).

As described above, the method for manufacturing the epitaxial wafer 20 or 22 according to the present embodiment includes the aftertreatment step (S21) to form the epitaxial layer 21 on the III-V compound semiconductor substrate 10 in the first embodiment.

According to the method for manufacturing the epitaxial wafer 20 or 22 in the present embodiment, on the surface 12a of the oxide film 12 of the III-V compound semiconductor substrate 10, the group V atoms exist in relatively large number, and the group III atoms exist relatively small number. In the formation of the epitaxial layer 21 by using the III-V compound semiconductor substrate 10, group V atoms falls off easily. However, since group V atoms are present to a large extent on the surface of the III-V compound semiconductor substrate 10 in the present embodiment, group V atoms unlikely to be small number on the surface of the epitaxial layer 21. Consequently, degradation in the stoichiometric balance between the group V atoms and group III atoms on the surface of the epitaxial layer 21 can be suppressed. Therefore, the epitaxial wafers 20 and 22 can be produced, in which the surface of the epitaxial layer 21 is prevented from getting rough.

Moreover, the III-V compound semiconductor substrate 10 in which variations in thickness of the oxide film 12 are suppressed is used. Therefore, in the aftertreatment step (S21), when the temperature is raised to form the epitaxial layer 21 on the III-V compound semiconductor substrate 10, O atoms in the oxide film 12 are electrically activated together with Si atoms taken in so as to form a deep level. Consequently, Si atoms, which have formed a shallow level, release carriers, and O atoms, which have formed a deep level, capture the carriers so as to electrically neutralize. As a result, in the formation of the epitaxial layer 21, the function of captured Si as an n-type carrier can be suppressed. Therefore, in the case where a semiconductor element is produced by using the III-V compound semiconductor substrate 10, deterioration in characteristics of the semiconductor element can be suppressed.

As described above, the function of Si as a carrier is suppressed. Consequently, in the epitaxial wafer 20 or 22 produced by the method for manufacturing the epitaxial wafer 20 or 22 in the present embodiment, the carrier concentration at an interface 10a between the III-V compound semiconductor substrate 10 and the epitaxial layer 21 can be reduced to less than 5×10¹⁴ cm⁻³.

### EXAMPLE 1

In the present example, an effect resulting from the cleaning step (S12) to clean the substrate with the acidic solution and the formation step (S13) to form the oxide film on the substrate by the wet method was examined.

### INVENTION EXAMPLES 1 to 8

Regarding each of Invention examples 1 to 8, basically, a III-V compound semiconductor substrate was produced following the first embodiment and, thereafter, an epitaxial wafer was produced following the second embodiment.

Specifically, initially in the preparation step (S11), a GaAs single crystal ingot formed from GaAs was prepared, and a substrate was prepared by slicing the GaAs single crystal ingot. Thereafter, the perimeter of the resulting substrate was chamfered.

Next, the substrate was subjected to lapping with segregation abrasive grains or grinding with fixed abrasive grains, so that the flatness of the substrate surface was improved and, in addition, the thickness was adjusted. Subsequently, the substrate was polished with a mixed solution of colloidal silica and chlorine based polishing solution and, thereafter, the substrate was polished with a chlorine based polishing solution. Then, the surface of the substrate was cleaned with choline (amine), followed by spin drying.

Then, in the cleaning step (S12), sheet spin drying of the substrate was conducted by using an acidic solution shown in Table described below. Thereafter, cleaning with hydrogen peroxide water as an oxidizing agent was conducted and, thereafter, spin drying was performed.

Subsequently, in the formation step (S13), an oxide film was formed on the substrate by using a solution shown in Table described below.

According to the above-described steps (S11 to S13), the III-V compound semiconductor substrates of Invention examples 1 to 8 were produced.

Next, in the aftertreatment step (S21), the III-V compound semiconductor substrate was subjected to a MOCVD method and, thereby, a GaAs layer (epitaxial layer) having a thickness of 1 μm was epitaxially grown. In this manner, epitaxial wafers of Invention examples 1 to 8 were produced.

### COMPARATIVE EXAMPLES 1 to 5

A III-V compound semiconductor substrate and an epitaxial wafer of Comparative example 1 were produced basically in the same manner as those in Invention examples 1 to 8 except that the cleaning step (S12) and the formation step (S13) were not carried out.

III-V compound semiconductor substrates and epitaxial wafers of Comparative examples 2 and 3 were produced basically in the same manner as those in Invention examples 1 to 8 except that the cleaning step (S12) was not carried out.

III-V compound semiconductor substrates and epitaxial wafers of Comparative examples 4 and 5 were produced basically in the same manner as those in Invention examples 1 to 8 except that in the cleaning step (S12), cleaning was conducted by using an alkaline solution shown in Table described below.

Measuring Method

Regarding the III-V compound semiconductor substrate of each of Invention examples of 1 to 8 and Comparative examples 1 to 5, the thickness of the oxide film and the reproducibility were measured by the following methods.

Regarding the thickness of the oxide film, the thickness of the oxide film formed at the center of the surface of the substrate was measured with an ellipsometric method.

The reproducibility was assumed to be σ/x, where five of the same III-V compound semiconductor substrate were produced in the same way, the average value of the oxide films on the substrates was assumed to be x, and the standard deviation was assumed to be σ.

Regarding the epitaxial wafers of Invention examples of 1 to 8 and Comparative examples 1 to 5, the surface roughness, the haze, and the number of defects were measured by the following methods.

Regarding the haze and the number of defects, the surface of the epitaxial layer was measured by using Surfscan 6220 produced by Tencor as a surface defect inspection system. Regarding the surface roughness, presence or absence of fine roughness was inspected all over the surface of the epitaxial layer visually under a focusing lamp of 300,000 lux. When the uniformity was observed all over the surface, it was evaluated as good, and when an occurrence of roughness was observed even in a part of the surface, it was evaluated as defective.

Furthermore, the sheet resistance and the carrier concentration at the interface between the III-V compound semiconductor substrate and the epitaxial layer were measured by the following methods.

Regarding the sheet resistance, the sheet resistances of the III-V compound semiconductor substrate and the epitaxial layer grown thereon were measured by using Reheighten serving as an eddy current sheet thickness measuring apparatus.

The carrier concentration was measured as described below. That is, a sample was produced by taking a chip of 3 mm long and 25 mm wide from the vicinity of the center of the epitaxial wafer in which the epitaxial layer was laminated on the III-V compound semiconductor substrate, and evaporating gold. The resulting sample was allowed to contact a probe, a voltage was applied, and a capacitance (C)-voltage (V) measurement was conducted. The carrier concentration in the vicinity of the interface between the III-V compound semiconductor substrate and the epitaxial layer was calculated from the measured C and V.

The results thereof are shown in Table described below.

TABLE 1

| | | | | | III-V compound | | | | | | |
|---|---|---|---|---|---|---|---|---|---|---|---|
| | | | | | semiconductor | | | | | | |
| | | | | | substrate | | Epitaxial layer | | | | |
| | Cleaning | | | | | Repro- | | | The number | Sheet | Carrier |
| | step | | Formation step | | Thickness | ducibility | Surface | Haze | of defects | resistance | concentration |
| | Solution | pH | Solution | pH | (Å) | (%) | roughness | (ppm) | (pcs) | (Ω/□) | (cm⁻³) |
| Invention | hydrofluoric | 4.8 | ozone water | 6.5 | 18 | 5.8 | good | 2.3 | 245 | 3.3 × 10⁵ | 3.9 × 10¹⁴ |
| example 1 | acid | | | | | | | | | | |
| Invention | hydrofluoric | 4.5 | hydrogen peroxide | 6.7 | 18 | 3.3 | good | 2.1 | 220 | 9.8 × 10⁵ | 5.0 × 10¹³ |
| example 2 | acid | | water | | | | | | | | |
| Invention | hydrofluoric | 6.0 | hydrogen peroxide | 6.4 | 17 | 3.1 | good | 2.8 | 310 | 7.1 × 10⁵ | 2.5 × 10¹⁴ |
| example 3 | acid | | water | | | | | | | | |
| Invention | hydrofluoric | 5.5 | hydrogen peroxide | 6.2 | 19 | 2.8 | good | 2.2 | 208 | 8.3 × 10⁵ | 1.9 × 10¹⁴ |
| example 4 | acid | | water | | | | | | | | |
| Invention | hydrofluoric | 2.0 | hydrogen peroxide | 6.3 | 18 | 2.9 | good | 2.2 | 215 | 9.8 × 10⁵ | 1.0 × 10¹³ |
| example 5 | acid | | water | | | | | | | | |
| Invention | hydrofluoric | 2.0 | hydrogen peroxide | 6.6 | 13 | 2.5 | good | 2.1 | 208 | 4.7 × 10⁴ | 1.2 × 10¹⁶ |
| example 6 | acid | | water | | | | | | | | |
| Invention | hydrofluoric | 2.0 | hydrogen peroxide | 6.2 | 15 | 2.4 | good | 2.1 | 198 | 6.3 × 10⁵ | 2.8 × 10¹⁴ |
| example 7 | acid | | water | | | | | | | | |
| Invention | hydrofluoric | 2.0 | hydrogen peroxide | 6.4 | 30 | 2.9 | good | 2.3 | 450 | 9.8 × 10⁵ | 1.0 × 10¹³ |
| example 8 | acid | | water | | | | | | | | |
| Comparative | — | — | — | — | 6 | — | good | 2.1 | 268 | 4.9 × 10³ | 2.3 × 10¹⁷ |
| example 1 | | | | | | | | | | | |
| Comparative | — | — | ozone water | 6.5 | 18 | 4.9 | defective | 2.8 | 469 | 6.0 × 10⁵ | 3.0 × 10¹⁴ |
| example 2 | | | | | | | | | | | |
| Comparative | — | — | hydrogen peroxide | 6.3 | 18 | 2.3 | defective | 2.9 | 478 | 8.3 × 10⁵ | 2.0 × 10¹⁴ |
| example 3 | | | water | | | | | | | | |
| Comparative | ammonia | 8.2 | ozone water | 6.7 | 17 | 4.9 | defective | 3.1 | 1489 | 5.2 × 10⁵ | 3.2 × 10¹⁴ |
| example 4 | water | | | | | | | | | | |
| Comparative | ammonia | 9.8 | ozone water | 6.5 | 18 | 4.8 | defective | 3.2 | 1385 | 5.6 × 10⁵ | 2.1 × 10¹⁴ |
| example 5 | water | | | | | | | | | | |

Measurement Results

As shown in Table, regarding the III-V compound semiconductor substrates of Invention examples 1 to 8 in which the cleaning step (S12) to clean the substrate with the acidic solution and the formation step (S13) to form the oxide film on the substrate by the wet method were carried out, the reproducibility (σ/x) of the oxide film was improved to 5.8% or less, the surface roughening of the epitaxial wafer was suppressed and, in addition, the sheet resistance at the interface between the III-V compound semiconductor substrate and the epitaxial wafer was a high, 4.7×10⁴ (Ω/□) or higher. Consequently, it was found that the thickness of the oxide film was able to be controlled with high precision, surface roughening was able to be suppressed when the epitaxial layer was formed and, in addition, the function of Si as an n-type dopant was able to be suppressed.

Moreover, the hazes of the surfaces of all epitaxial wafers of Invention examples 1 to 8 were a low, 2.8 ppm or less. In addition, the number of defects on the surface of the epitaxial wafer of Invention examples 1 to 8 was a small, 450 pcs or less.

Particularly, in Invention examples 1 to 5, 7, and 8 in which the thicknesses of the oxide films were 15 Å or more, and 30 Å or less, the interface between the III-V compound semiconductor substrate and the epitaxial layer had the sheet resistance of 3.3×10⁵ (Ω/□) or more and the carrier concentration of 3.9×10¹⁴ cm⁻³ or less. Consequently, it was made clear that the function of Si as an n-type dopant was able to be suppressed effectively by specifying the thickness of the oxide film to be 15 Å or more, and 30 Å or less.

In addition, in Invention examples 2 to 8 in which oxide films were formed by using the hydrogen peroxide water, the reproducibility of the oxide film was 3.3% or less and the thickness of the oxide film was controlled with very high precision.

On the other hand, in Comparative example 1 in which the cleaning step (S12) and the formation step (S13) were not carried out, activation of Si was not able to be suppressed at the interface between the III-V compound semiconductor substrate and the epitaxial layer, although an oxide film was formed spontaneously.

Furthermore, regarding Comparative examples 2 and 3 in which the cleaning step (S12) was not performed and the formation step (S13) was performed, since the neutral solution was used in the formation step, surface roughening of the epitaxial layer was not able to be suppressed. Moreover, in Comparative examples 4 and 5 in which the cleaning was conducted by using the alkaline solution instead of the acidic solution, surface roughening was not able to be suppressed. The reasons therefor are believed to be as described below. That is, a spontaneous oxide film containing Ga oxides, e.g., Ga₂O₃, and As oxides, e.g., As₂O₃, is formed on the surface of the GaAs substrate. This spontaneous oxide film is dissolved into an acidic solution easily, but in an alkaline or neutral region, dissolution of the As oxides is a very large extent as compared with dissolution of the Ga oxides. Consequently, in the case where an alkaline or neutral solution contacts the substrate, the surface of the III-V compound semiconductor substrate becomes a Ga-rich surface in which Ga, which is a group III atom, exists to a large extent and, in addition, unevenness (concavity and convexity) occurs on the surface. When the epitaxial layer is formed in this state in the aftertreatment step (S21), As, which is a group V atom, further falls off, and degradation in the stoichiometric balance between the Ga atoms and As atoms occurs.

As described above, according to the present example, it was ascertained that the III-V compound semiconductor substrate and the epitaxial wafer, wherein the thickness of the oxide film was able to be controlled with high precision and surface roughening was suppressed when the epitaxial layer was formed, were able to be produced by performing the cleaning step (S12) to clean the substrate with the acidic solution and the forming step (S13) to form the oxide film on the substrate by the wet method.

### EXAMPLE 2

In the present example, an effect of formation of the oxide film was examined. Specifically, each ten III-V compound semiconductor substrates were produced under the same conditions as those of the above-described III-V compound semiconductor substrates of Invention example 2 and Comparative example 1.

Next, each five substrates of III-V compound semiconductor substrates produced in a manner similar to those of Invention example 2 and Comparative example 1 were held at 550° C. for 15 minutes while a hydrogen gas and an arsine gas were supplied (thermal cleaning). Subsequently, in the aftertreatment step (S21), an epitaxial layer was formed on each of the III-V compound semiconductor substrates at 580° C. under the same condition as that in Invention example 2 or Comparative example 1.

Furthermore, the remaining five III-V compound semiconductor substrates were held at 730° C. for 15 minutes while the same gases were supplied (thermal cleaning). Subsequently, in the aftertreatment step (S21), an epitaxial layer was formed on each of the III-V compound semiconductor substrate at 580° C. under the same condition as that in Invention example 2 or Comparative example 1.

Measuring Method

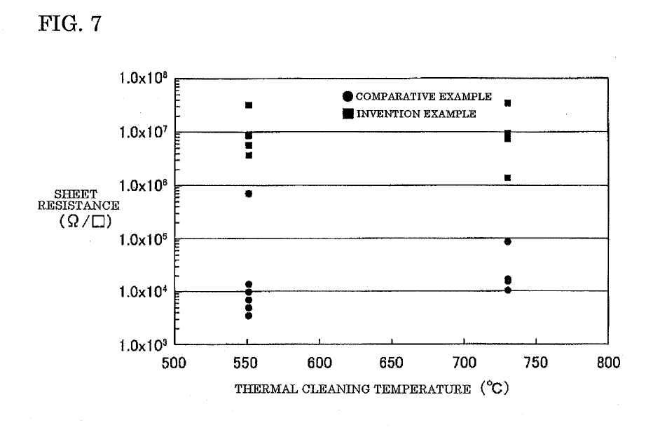

Regarding each of the epitaxial wafers, the resistance (sheet resistance) was measured as in the same manner as that in Example 1. The results thereof are shown in FIG. 7. In this regard, FIG. 7 is a diagram showing the relationship between the thermal cleaning temperature and the resistance at the interface between the III-V compound semiconductor substrate and the epitaxial wafer. In FIG. 7, the vertical axis indicates the resistance (unit: Ω/□) and the horizontal axis indicates the thermal cleaning temperature (unit: ° C.).

Measurement Results

As shown in FIG. 7, the III-V compound semiconductor substrate and the epitaxial wafer similar to those in Invention example 2 in which the oxide film was formed had high resistance which is independent of the thermal cleaning temperature. On the other hand, the resistance of the III-V compound semiconductor substrate and the epitaxial wafer of Comparative example 1 in which the oxide film was not formed were increased by raising the thermal cleaning temperature.

As described above, according to the present example, it was made clear that an epitaxial wafer having the desired characteristics was able to be produced by forming the oxide film independent of the production condition, e.g., the thermal cleaning condition of the III-V compound semiconductor substrate. Moreover, according to the present invention in which the oxide film was formed, it was made clear that since thermal cleaning is unnecessary immediately before the formation of the epitaxial layer, the cost required for forming the epitaxial wafer was able to be reduced.

It is to be understood that the embodiments and examples disclosed above are no more than exemplifications and are not limitative. The scope of the present invention is not determined by the above-described embodiments, but by the scope of the claims. The invention is intended to cover all modifications and equivalent arrangements included within the spirit and scope of the claims.

What is claimed is:

1. A method for manufacturing a III-V compound semiconductor substrate comprising the steps of:
preparing a substrate composed of a III-V compound semiconductor;
cleaning the substrate with an acidic solution; and
forming an oxide film on the substrate by a wet method after the cleaning.

2. The method for manufacturing a III-V compound semiconductor substrate according to claim 1, wherein in the forming an oxide film, the oxide film having a thickness of 15 Å or more, and 30 Å or less is formed.

3. The method for manufacturing a III-V compound semiconductor substrate according to claim 1, wherein in the cleaning, the acidic solution having a pH of 6 or less is used.

4. The method for manufacturing a III-V compound semiconductor substrate according to claims 1, wherein in the forming an oxide film, the oxide film is formed by using hydrogen peroxide water.

5. The method for manufacturing a III-V compound semiconductor substrate according to claims 1, wherein in the preparing, the substrate composed of GaAs, InP, or GaN is prepared.

6. A method for manufacturing an epitaxial wafer, the method comprising the steps of:
producing a III-V compound semiconductor substrate by the method for manufacturing a III-V compound semiconductor substrate according to claims 1; and
forming an epitaxial layer on the III-V compound semiconductor substrate.

7. A III-V compound semiconductor substrate produced by the method for manufacturing a III-V compound semiconductor substrate according to claims 1.

8. The III-V compound semiconductor substrate according to claim 7, wherein the oxide film has a thickness of 15 Å or more, and 30 Å or less.

9. An epitaxial wafer comprising:
the III-V compound semiconductor substrate according to claim 7; and
an epitaxial layer disposed on the III-V compound semiconductor substrate.
